(19) United States
(12) Patent Application Publication
(10) Pub. No.: US 2020/0144437 A1
(43) Pub. Date: May 7, 2020

(54) WAVEGUIDE INTEGRATED PLASMONIC SCHOTTKY PHOTODETECTOR

(71) Applicant: NEW YORK UNIVERSITY, New York, NY (US)

(72) Inventor: JACEK GOSCINIAK, LODZ (PL)

(21) Appl. No.: 16/539,029

(22) Filed: Aug. 13, 2019

Related U.S. Application Data
(60) Provisional application No. 62/718,116, filed on Aug. 13, 2018.

(51) Int. Cl. H01L 31/108; H01L 31/0232; H01L 27/146; H01L 31/028; H01L 31/18

(52) U.S. Cl. CPC H01L 31/1085; H01L 31/0232; H01L 31/1804; H01L 31/028; H01L 27/14643

(57) ABSTRACT

An exemplary photodetector can be provided, which can include, for example, a metal contact, a metal stripe coupled to the metal contact. The semiconductor(s) can surround the metal stripe on at least three sides of the metal stripe. The semiconductor(s) can surround the metal stripe on at least four sides. The semiconductor can surround the metal stripe on at least five sides. A silicon dioxide layer can be coupled to the at least one semiconductor. A graphene layer located can be between the metal stripe and the semiconductor(s).

### CROSS-REFERENCE TO RELATED APPLICATION(S)

This application relates to and claims priority from U.S. Patent Application No. 62/718,116, filed on Aug. 13, 2018, the entire disclosure of which is incorporated herein by reference.

### FIELD OF THE DISCLOSURE

The present disclosure relates generally to a photodetector, and more specifically, to exemplary embodiments of an exemplary waveguide integrated plasmonic Schottky photodetector.

### BACKGROUND INFORMATION

One of the main challenges of plasmonic photodetectors is to efficiently convert the absorbed photons on a photocurrent. Thus, it may be beneficial to provide an exemplary waveguide integrated plasmonic Schottky photodetector which can overcome at least some of the deficiencies described herein above.

### SUMMARY OF EXEMPLARY EMBODIMENTS

An exemplary photodetector can be provided, which can include, for example, a metal contact and, a metal stripe coupled to the metal contact. The metal stripe can be placed symmetrically in the middle of the ridge or asymmetrically. The semiconductor(s) can surround the metal stripe on at least three sides of the metal stripe. The semiconductor(s) can surround the metal stripe on at least four sides. The semiconductor can surround the metal stripe on at least five sides. A low refractive index layer can be coupled to the at least one semiconductor. A graphene layer located can be between the metal stripe and the semiconductor(s).

In some exemplary embodiments of the present disclosure, the semiconductor(s) can include a first semiconductor and a second semiconductor. The first semiconductor can surround the metal stripe on three sides and the second semiconductor can surround the metal stripe on one side. A low refractive index layer can be included, where the first semiconductor can be disposed on the low refractive index layer and a graphene layer can be disposed on the first semiconductor layer. The metal stripe can be disposed on the graphene layer such that the graphene layer surrounds the metal stripe on one side. The second semiconductor can surround the metal stripe on four sides, and the second semiconductor can be coupled to the graphene layer.

In certain exemplary embodiments of the present disclosure, a low refractive index layer can be included whereas the semiconductor layer can be disposed on the silicon dioxide layer and the semiconductor layer can surround the metal stripe on one side. A graphene layer can surround the metal stripe on 4 sides, and the second semiconductor can be coupled to the graphene layer. The metal contact can be disposed on the semiconductor(s). A further metal contact can be included, which can be disposed on the semiconductor(s). The metal contact and the metal stripe can be composed of titanium nitride or any other metallic material. The semiconductor(s) can be an insulator. The photodetector can be configured to operate at a wavelength of between about 1260 nm to about 1625 nm. The metal stripe can be a plasmonic stripe.

Additionally, an exemplary photodetector can include, for example, a first semiconductor, a first metal contact disposed on the first semiconductor, a metal stripe coupled to the first metal contact, the first semiconductor can surround the metal stripe on one side of the metal stripe, a second semiconductor surrounding the metal stripe on at least three sides of the metal stripe, and a second metal contact disposed on the first semiconductor.

Further, an exemplary method of fabricating a photodetector can be provided which can, for example, form a silicon dioxide layer, form a first semiconductor layer on the silicon dioxide layer, form a metal stripe on the first semiconductor layer such that the first semiconductor layer surrounds the metal stripe on one side, and form a second semiconductor layer on the metal stripe and the first semiconductor such that the second semiconductor can be coupled to the first semiconductor, and the second semiconductor can surround the metal stripe on three sides of the metal stripe.

These and other objects, features and advantages of the exemplary embodiments of the present disclosure will become apparent upon reading the following detailed description of the exemplary embodiments of the present disclosure, when taken in conjunction with the appended claims.

### BRIEF DESCRIPTION OF THE DRAWINGS

Further objects, features and advantages of the present disclosure will become apparent from the following detailed description taken in conjunction with the accompanying Figures showing illustrative embodiments of the present disclosure, in which:

FIG. 1 is an exemplary diagram of cross-section of an exemplary LR-DLSPP waveguide partially embedded into a ridge according to an exemplary embodiment of the present disclosure.

FIG. 2 is an exemplary diagram of cross-section of the exemplary LR-DLSPP waveguide entirely embedded into a ridge according to an exemplary embodiment of the present disclosure;

FIG. 3 is an exemplary diagram of the perspective view of a photodetector arrangement according to an exemplary embodiment of the present disclosure;

FIG. 4 is an exemplary illustration of metal—Si Schottky barriers and a k-space emission cone according to an exemplary embodiment of the present disclosure;

FIG. 5 is a set of exemplary electric field maps for the mode effective index and losses for the exemplary LR-DLSPP waveguide with gold and titanium nitride strips according to an exemplary embodiment of the present disclosure;

FIG. 6 is a set of exemplary graphs of the real and imaginary parts of the permittivity for gold and titanium nitride according to an exemplary embodiment of the present disclosure;

FIG. 7 is an exemplary view of the cross-section of the exemplary LR-DLSPP waveguide arrangement with graphene below a metal stripe according to an exemplary embodiment of the present disclosure;

FIG. 8 is an exemplary view of the cross-section of the exemplary LR-DLSPP waveguide arrangement with graphene above a metal stripe according to an exemplary embodiment of the present disclosure;

FIG. 9A is an exemplary diagram of a single interface metal stripe according to an exemplary embodiment of the present disclosure;

FIG. 9B is an exemplary diagram of a metal strip embedded in a semiconductor according to an exemplary embodiment of the present disclosure;

FIG. 10A is an exemplary graph illustrating the real part of the permittivities for common metals with TiN fabricated under different deposition conditions according to an exemplary embodiment of the present disclosure;

FIG. 10B is an exemplary graph illustrating the imaginary part of the permittivities for common metals with TiN fabricated under different deposition conditions according to an exemplary embodiment of the present disclosure:

FIG. 11A is an exemplary graph illustrating characteristics of the fabricated TiN—Si junction for different TiN contact areas for n-doped Si according to an exemplary embodiment of the present disclosure;

FIG. 11B is an exemplary graph illustrating characteristics of the fabricated TiN—Si junction for different TiN contact areas for p-doped Si according to an exemplary embodiment of the present disclosure;

FIG. 12A is an exemplary graph illustrating measurement for TiN on n-Si according to an exemplary embodiment of the present disclosure;

FIG. 12B is an exemplary graph illustrating measurement for TiN on p-Si according to an exemplary embodiment of the present disclosure;

FIG. 12C is an exemplary graph illustrating temperature dependent electrical characterization of the TiN-p-Si contact according to an exemplary embodiment of the present disclosure;

FIG. 13A is an exemplary energy band diagram of the Au—Si—TiN junction in thermal equilibrium with no bias voltage according to an exemplary embodiment of the present disclosure;

FIG. 13B is an exemplary energy band diagram of the Au—Si—TiN junction in non-equilibrium under applied forward bias voltage V according to an exemplary embodiment of the present disclosure;

FIG. 14A is an exemplary diagram of the cross-section of the exemplary measurement setup according to an exemplary embodiment of the present disclosure;

FIG. 14B is an exemplary diagram of the top down view of the measurement setup according to an exemplary embodiment of the present disclosure;

FIG. 15 is an exemplary flow diagram of an exemplary method of fabricating a photodetector according to an exemplary embodiment of the present disclosure; and

FIG. 16 is an illustration of an exemplary block diagram of an exemplary system in accordance with certain exemplary embodiments of the present disclosure.

Throughout the drawings, the same reference numerals and characters, unless otherwise stated, are used to denote like features, elements, components or portions of the illustrated embodiments. Moreover, while the present disclosure will now be described in detail with reference to the figures, it is done so in connection with the illustrative embodiments and is not limited by the particular embodiments illustrated in the figures.

### DETAILED DESCRIPTION OF EXEMPLARY EMBODIMENTS

In the exemplary Schottky barrier photodetector, the coupling efficiency from a photonic waveguide to a photodetector in the range of 90-98% can be possible as a result of high mode overlap between photonic and plasmonic waveguides, thus providing high external responsivity of the photodetector. Therefore, the exemplary arrangement can ensure a monolithic component integration where optical devices and transistors can all be included on the same die. This can simplify packing, and can facilitate tighter device-to-circuit proximity to lower parasitics. It can also facilitate the use a silicon for a photodetectors operating at telecom wavelength, for example, between about 1260 nm to about 1625 nm (e.g., about 1200 nm to about 1700 nm), which additionally simplifies the fabrication process.

Photodetectors (“PDs”) can be one of the building blocks of an optoelectronic link that can convert light into an electrical signal. The monolithic, on-chip, optoelectronic integration benefits from development of complementary metal-oxide-semiconductor (“CMOS”) compatible PDs operating in the telecom wavelengths (e.g., 1.1-1.7 μm) based on the CMOS technology. (See, e.g., References 1-3). Although sensitivity can be a beneficial attribute for photodetectors in long distance communications, for short distance interconnects, another factor can be the total energy dissipated per bit. The optical energy received at the photodetector can be directly related to the transmitter optical output power, and the total link loss power budget, which can include total link attenuation, coupling losses and eventually, a power margin. Thus, for 10 fJ/bit transmitted optical energies, the received optical energy can be 1 fJ/bit. Therefore, minimizing the optical losses at the photodetector can be beneficial for overall performance of the system.

Photodetectors can operate on the basis of the photoelectric effect or exhibit an electrical resistance dependent on the incident radiation. This can be based on the absorption of photons and the subsequent separation of photogenerated charge carriers—electron-hole (“e-h”) pairs. However, they can suffer from low efficiency either because the near infrared (“NIR”) photons energy at telecom wavelengths (e.g., 0.79-0.95 eV) may not be sufficient to overcome the Si bandgap (e.g., 1.12 eV) or low detection area in the case of Ge-based photodetectors (e.g., bandgap 0.67 eV). Other exemplary approaches can utilize the intrinsic absorption of metal for photodetection that can be accomplished by internal photoemission (“IPE”) in a Schottky diode. (See, e.g., References 19-26). In this exemplary configuration, photoexcited (“hot”) carriers from the metal can be emitted to semiconductor/insulator over a potential Φ_{B}, called a Schottky barrier that can exist at the metal-semiconductor/insulator interface. In semiconductor/insulator, the injected carriers can be accelerated by an electric field in the depletion region of a Schottky diode and then collected as a photocurrent at the external electrical contacts. A Schottky barrier can be lower than the bandgaps of most of the semiconductors, thus facilitating a photodetection of NIR photons with energy hv>Φ_{B}. The process of photo-induced emission of electrons from metals and its collection can include an exemplary three-step model: (i) generation of hot electrons in the metal through the absorption of photons, (ii) diffusion a portion of the hot electrons to the metal-semiconductor/insulator interface before thermalization, and (iii) injection of hot electrons with sufficient energy and the correct momentum into the conduction band of the semiconductor/insulator through internal photoemission.

To enhance the efficiency of the IPE process, it can be beneficial to confine the optical power at the boundary between materials forming the Schottky barrier. This can facilitate the increase in the interaction of light with the metal in very close vicinity of the interface where the photoemission process takes place. This can be called a surface plasmon polariton (“SPP”). The SPP can guide optical surface waves propagating along the boundary between metal and dielectric with the maximum field located in this interface and decaying exponentially in both media. (See, e.g., References 6 and 7). An advantage of SPP can be based on the fact that it may not be diffraction limited, and it can facilitate a tight confinement of an optical field to subwavelength dimensions. The SPP can provide long interaction length between the propagating mode and the photodetector, thus facilitating a larger portion of the optical energy to be absorbed nearby the Schottky barrier. Plasmonic photodetectors can have high integration densities, low device capacitance, which can facilitate higher bandwidth operation, and ultra-low energies to operate.

Surface plasmon polaritons can be electromagnetic surface waves which can be coherently coupled to charge carrier density fluctuations on a metal, and can propagate at the interface between a metal and an insulator/semiconductor for example, between materials with opposite signs of a real part of the permittivity. (See, e.g., References 6 and 7). The negative real part of a permittivity in metals can be related to the collective motion of the conduction electrons, plasma oscillations. Analogously to the photon, they can exhibit wave-like and particle-like behavior. However, compared to the photons, they may not be a diffraction limited, and they can support intense electromagnetic field concentration at the interface between metal and semiconductor/insulator. Surface plasmon can decay, either radiatively via emission of photons or non-radiatively through the generation of excited carriers, so called hot carriers. These photo-excited hot carriers can overcome the potential barrier between metal and semiconductor/insulator, which can lead to a light-induced charge separation and thus a measurable current. Furthermore, the potential barrier can be overcome either directly or through the quantum mechanical tunnel effects with the probability dependent on the barrier width and height as well as the charge carrier energy.

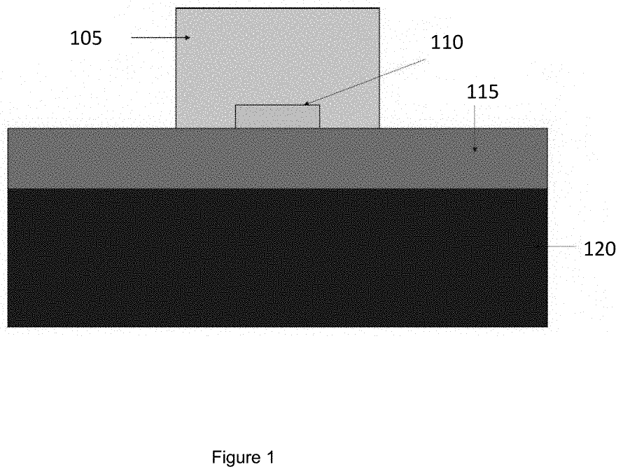

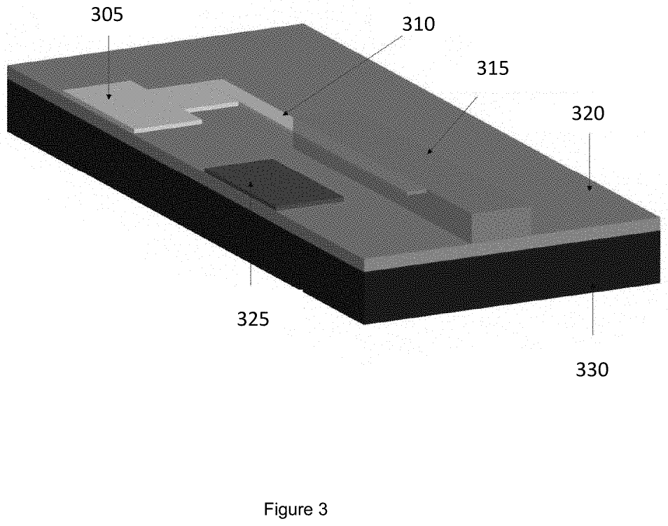

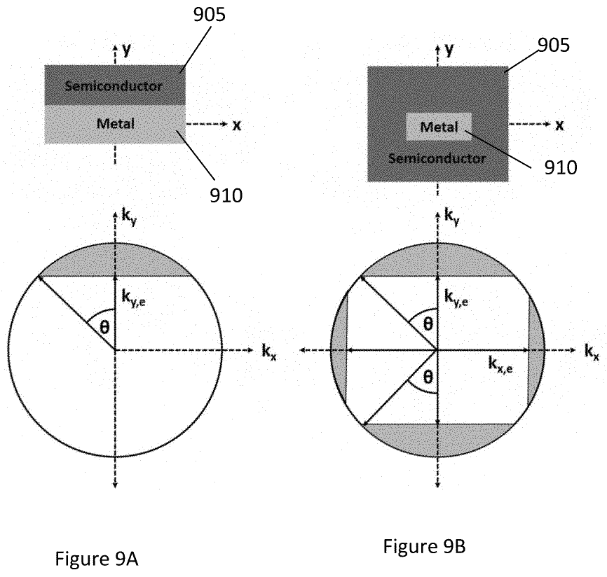

FIG. 1 shows an exemplary diagram of cross-section of an exemplary LR-DLSPP waveguide partially embedded into a ridge according to an exemplary embodiment of the present disclosure. To improve transmission probability of hot carriers from metal 110 to semiconductor 115, which can be disposed on a SiO₂ layer 120, it can be beneficial to place a metal stripe 110 inside a semiconductor 105. Compared to previous arrangement that use a metal-semiconductor-metal (“MIM”) waveguide (see, e.g., References 12 and 34) or inverse-DLSPP waveguide with metal electrode on top of the Si waveguide (see, e.g., References 13-16), in the exemplary Schottky barrier photodetector (see e.g., FIG. 3), more hot carriers can participate in a transition to the semiconductor as a metal electrode can be embedded inside a semiconductor. In the thin metal stripe 115 embedded into the semiconductor 105, the Schottky barrier can exist on both sides of the metal-semiconductor interface. Thus the probability of emission of photo-excited carrier can be doubled due to the doubling of the interfaces. (See e.g., diagrams shown in FIGS. 9A and 9B). Additionally, it can be further increased due to multiple carrier reflections within the metal film. In the MIM arrangement, most of the hot carriers can actually move in the opposite direction to the junction and after a short period of time can be thermalized. Furthermore, only a part of the SPP can be dissipated in a desired interface (e.g., Ti—Si) and can participate in the hot carrier generation. The hot carriers generated in the opposite junction (e.g., Au—Si) can give rise to a dark current in high photon energies. In the inverse-DLSPP arrangements (see, e.g., References 13-16), only a small fraction of hot carriers can participate in transition to the semiconductor 105, as most of them can move in other directions that may not give a rise to a photoemission process.

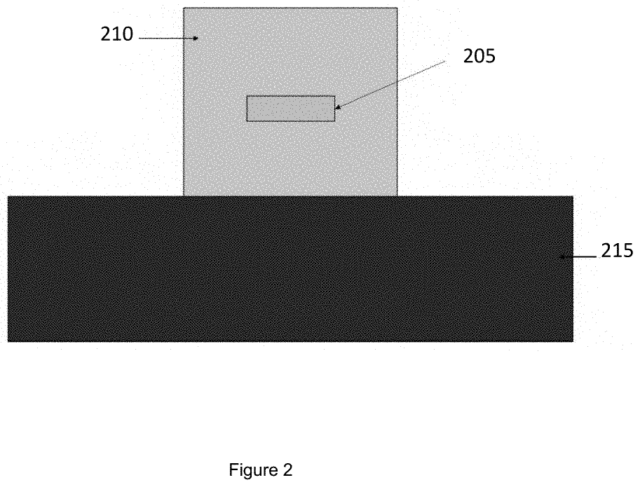

FIG. 2 shows an exemplary diagram of cross-section of the exemplary LR-DLSPP waveguide entirely embedded into a ridge according to an exemplary embodiment of the present disclosure. For example, as shown in FIG. 2, metal strip 205 can be embedded entirely in semiconductor 210. Semiconductor 210 can be disposed on SiO₂ layer 215. Thus, in contrast to the arrangement shown in FIG. 1, only a single semiconductor is utilized in FIG. 2.

Embedding the plasmonic stripe within the semiconductor can boost the hot electron transfer efficiencies by providing more momentum space for hot electron emission. (See, e.g., Reference 18). Plasmonic stripe embedded in the semiconductor can form a 3D Schottky barrier on all sides of the plasmonic stripe (see e.g., diagram shown in FIG. 9B) (see, e.g., Reference 18) compared to the planar Schottky interface in MIM (see, e.g., Reference 12), inverse-DLSPP (see, e.g., References 13-16) or metal stripe on semiconductor (see, e.g., Reference 17) photodetector arrangements. It was experimentally shown (see, e.g., Reference 18) that for the same number of photons absorbed by metal stripe, the structures embedded in the semiconductor can produce higher responsivity that can be directly attributed to an enhancement in charge injection over the additional Schottky barriers. Furthermore, a higher photocurrent enhancement for thinner stripes was observed indicating the major contribution of the ballistic hot electrons produced by plasmon decay. The embedded nanowires, under normal incidence can have 25× greater efficiency than comparable planar Schottky devices indicating that 3D Schottky barriers can be a beneficial design feature for increasing the efficiency of plasmon-based photodetectors.

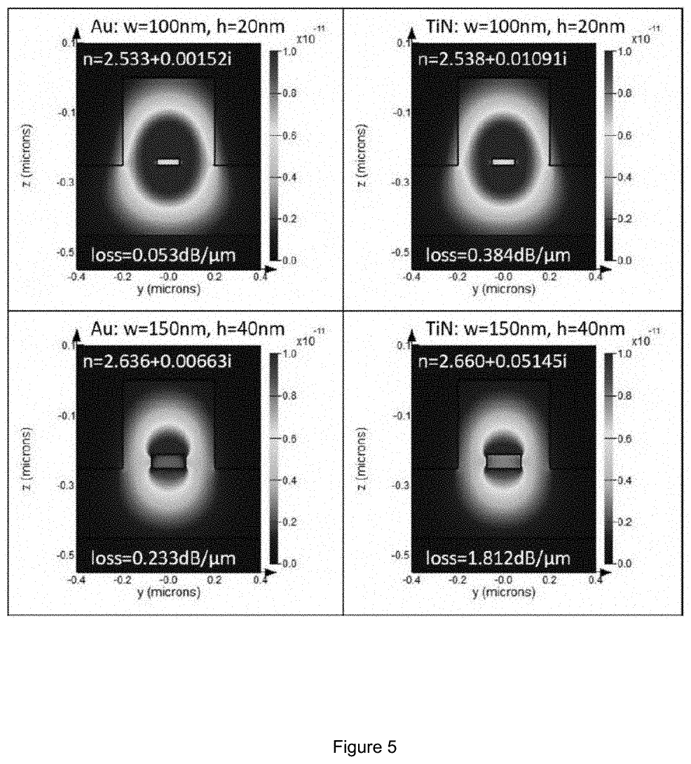

FIG. 3 shows a perspective view diagram of a photodetector arrangement according to an exemplary embodiment of the present disclosure. The exemplary Schottky barrier photodetector can include a metal stripe 310 embedded in the semiconductor/insulator material 315. Metal stripe 310 can be coupled to a first metal contact 305, which can be disposed on a semiconductor layer 320. Semiconductor layer 320 can be disposed on a SiO₂ layer 330. Additionally, a second metal contact 325 can be disposed on semiconductor 320. As shown in FIG. 3, for a metal stripe 310 embedded in a dielectric there can be two SPPs on each side of the metal-dielectric interfaces that can be bounded to the metal interface, and with the electromagnetic energy located partially in the metal and dielectric. (See e.g., electric field maps shown in FIG. 5). The amount of the energy in the metal and dielectric can depend on the material optical properties and waveguide geometry.

The penetration depth of the electromagnetic field into the dielectric can depend on the permittivity of the semiconductor/insulator and the plasmonic waveguide configuration, and it can typically be on the order of λ/2. In contrast, the penetration depth of light into a metal, so called the skin depth, can depend on the metal optical properties. Thus, a large negative real permittivity, that can be a consequence of larger plasma frequency or larger carrier concentration, can provide a small penetration into the metal, while a small imaginary permittivity can lead to lower losses. The skin depth in the metal can usually be in the range of about 10-20 nm. Based on this, the field penetration into the metal can influence the trade-off between confinement and propagation losses—the less light inside the metal and more inside the dielectric, the smaller the loss and smaller confinement. To reduce the absorption losses, the longitudinal component of the electric field in the metal that can be responsible for the absorption losses to be minimized. For the case of the metal stripe embedded into dielectric ridge, it can be achieved by decreasing (e.g., reducing) the metal stripe thickness below the penetration depth of the of the SPP into metal, so the two SPP modes associated with two opposite interfaces can overlap and form new SPP wave with an increased propagation range, so called long-range dielectric-loaded SPP (“LR-DLSPP”). (See, e.g., References 8-11). In this exemplary case, the longitudinal component of the electric field in the metal can be minimized. LR-DLSPP can denote the plasmonic waveguide where the metal stripe can be embedded either ‘partially’ (see e.g., FIG. 1) or ‘entirely’ (see e.g., FIG. 2) inside a dielectric/semiconductor ridge that can ensure sufficient mode confinement.

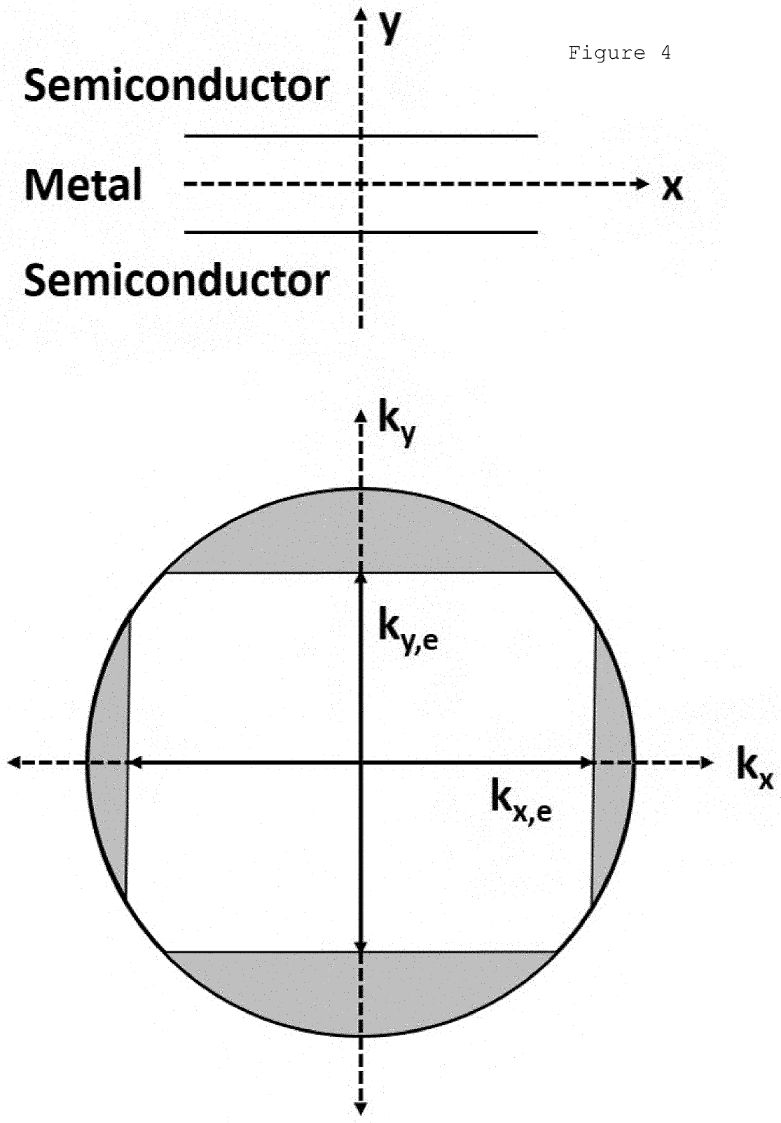

The SPP propagating on each side of the plasmonic stripe embedded into semiconductor along the metal-semiconductor interface can generate hot electrons in close proximity to the Schottky interface. Because of the nature of the SPP, the electric field component can be perpendicular to the interface that includes the generation of hot electrons with a momentum vector perpendicular to the Schottky interface. Furthermore, the sharp corners of the metal stripe can compress the SPPs producing hot electrons with high momentum perpendicular to the interface, and thus can further enhancing the photoemission efficiency. (See e.g., FIG. 4; and Reference 19). For example, FIG. 4 shows an exemplary illustration of metal—Si Schottky barriers and a k-space emission cone according to an exemplary embodiment of the present disclosure. In the exemplary LR-DLSPP arrangement, the highest electric field can be localized in all four corners, which can enhance a photoemission process.

A source of losses in the exemplary arrangement can be absorption losses by the metal stripe. To compare absorption losses and the mode effective index two different metals were used, Au and TiN, and two different metal dimensions, for example, w=100 nm, h=20 nm, and w=150 nm, h=40 nm. Ridge dimension and rib thickness were kept constant at w=380 nm, h=200 nm and t=140 nm respectively. Power absorbed by the metal stripe generated hot electrons that can participate in a transition to semiconductor. Thus, the more power absorbed by the metal stripe, the higher probability of hot electron transfer. As shown in the electric field maps in FIG. 5, it can be observed that the thicker the metal stripe, the higher the absorption losses. However, the thicker metal stripe, the higher real part of mode effective index and higher coupling losses between photonic waveguide and photodetector. As the stripe becomes thicker, the internal quantum efficiency arises, however, the external quantum efficiency decreases as an effect of lower coupling efficiency. Thus, special care is needed for the choice of the metal stripe dimensions. Simultaneously, the absorption losses can be higher for TiN compared to Au that can be directly related with the real and imaginary part of permittivities—TiN has lower negative real part of permittivity and higher imaginary part, which can enhance absorption. For the same metal stripe dimensions, TiN can provide over 7 times higher absorption compared to Au, and only slightly higher real part of mode effective index (e.g., difference of 0.05 for metal stripe dimensions of w=100 nm and h=20 nm), which makes it favorable material for such a photodetector. Usually, the lower negative real part of permittivity, the longer electric field penetration depth into metal. However, in the exemplary arrangement all the power can be absorbed in very thin metal stripe very close to the metal-semiconductor interface, thus, most of the carriers can participate in a transition without experiencing any scattering with other carriers.

The exemplary Schottky barrier photodetector can take advantages of two SPP modes that can interact with a small volume metal stripe; thus more electrons can interact with the electro-magnetic energy providing higher efficiency in the IPE process, and the higher photoemission. For a very thin metal stripe, there can be an increased probability of hot carriers crossing the metal junction before a thermalization. The exemplary design can provide superior coupling efficiency from a photonic waveguide to a photodetector, calculated at 98% for both aluminum (see, e.g., Reference 11) and gold (see, e.g., Reference 10) stripes compared to MIM and inverse-DLSPP arrangements where the coupling efficiencies were estimated at 50-60%. The improved coupling efficiency for the exemplary LR-DLSPP mode can result from the similar mode profile of the photonic and fundamental LR-DLSPP modes. Higher coupling efficiency can mean that less light radiates through the coupling due to the mode mismatch (see, e.g., Reference 15) and more light decay in the non-radiative direction by interaction with the metal, providing hot carrier generation and improved photocurrent efficiency.

Compared to the other designs with the MIM (see, e.g., Reference 12) and inverse-DLSPP (see, e.g., References 13-15) arrangements where the electron can have only 50% probability to arrive at the metal-semiconductor interface, as it can travel either towards the interface or away from it (see, e.g., Reference 16), in the exemplary Schottky barrier photodetector, this probability can reach 100%, as the metal stripe can be embedded in the semiconductor, and all interfaces can participate in a transition. Furthermore, as the metal stripe thickness for the LR-DLSPP arrangement can be in the range from a few to tens of nanometers, the probability of inelastic collisions, and thermalization can drop significantly for thinner metal stripes.

Non-radiative decay of SPP can produce hot electrons in the metal that can move towards the metal-semiconductor interface. As the metal stripe can be entirely embedded in the semiconductor, most of the hot electrons can arrive to the interface. Taking into account a very thin metal stripe supporting a propagating mode that can be in the range of 5-50 nm, or 20-40 nm, and a mean free path of the electrons in metals (e.g., 30-100 nm), most of the electrons can arrive at the interface without undergoing inelastic collisions. The hot electrons arriving at the metal-semiconductor interface with a kinetic energy exceeding the Schottky barrier Φ_{B} have a certain probability of jumping through the barrier. To pass the barrier, electrons have to conserve their energy and momentum tangential to the interface upon transmission through the barrier. Thus, metals with a lower Fermi level, and with small band offset with the semiconductor material, can be beneficial. The impedance mismatch, a large wavevector contrast, between electrons in the metal and barrier, can be alleviated in the corners of the metal stripe where the electric field can be highly localized. Additionally, the efficiency of the internal photoemission process can be enhanced in the rough metal-semiconductor contacts due to the presence of localized high density electric fields at the sharp edges of surface imperfections. It can be used to relax the momentum conversion rules at the interface, and can thus facilitate the photoexcited electrons that otherwise can been totally reflected back into the metal, to enter the semiconductor. It was observed that a longer interaction length in plasmonic waveguide can boost the efficiency of a photodetector. Furthermore, the hot electrons can be directed along the polarization of the excited SPP, what makes transition to the semiconductor more probable. For very thin semiconductor layers, the tunneling through the barrier can be considered as well, which can be possible for the hot electron energies that can be below the Schottky barrier. (See, e.g., Reference 24).

With decreasing metal thickness, the probability of generating hot electrons via intraband transition increases. As the plasmonic wavevector establishes a light wavevector, the smaller fraction of the field can be in the interior of the metal, which can lower the contribution of the interband transitions. For metal films smaller than about 10 nm, the probability of intraband transitions arises, which can facilitate the generation of hotter electrons for some metals like cooper and gold. (See, e.g., Reference 20).

### Exemplary Transition Metal Nitrides

Apart from the most common metals used for a photodetection such as gold, silver, copper and aluminium, the transition metal nitrides can exhibit gold-competitive optical properties that can be modified during the fabrication process while also providing thermal and chemical stability and compatibility with CMOS technology. TiN is one transition metal nitride. (See, e.g., References 27 and 28). It can have a work function of Φ_{M}=4 eV, which can be much lower than the value for Au−Φ_{M}=5.2 eV. Furthermore, the barrier height between gold and n-doped silicon can be Φ_{Au-Si}=0.82 eV compared to ϕ_{TiN-Si}=0.5-0.6 eV for TiN—Si interface. Thus, for the same photon energy, TiN can provide higher photoemission efficiencies as compared to Au.

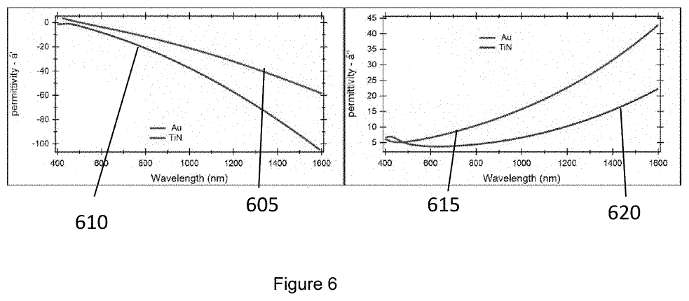

As shown in the graphs of FIG. 6, the magnitude of the real part of TiN (line 605) can be smaller than that of gold (line 610) and the imaginary part of TiN (line 615) can be larger than that of gold (line 620) above approximately 500 nm. Thus, TiN can provide higher absorption efficiencies in a wider wavelength range, which can enhance hot electron generation. (See e.g., diagram shown in FIG. 4). It can be expected that losses exceeding 3-4 dB/μm can be achievable with TiN.

### Exemplary Graphene and 2D Materials

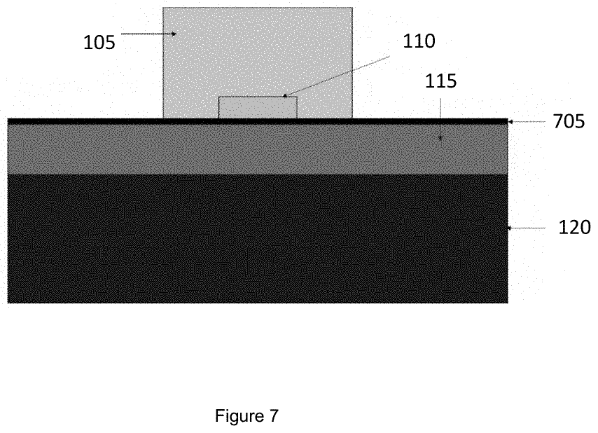

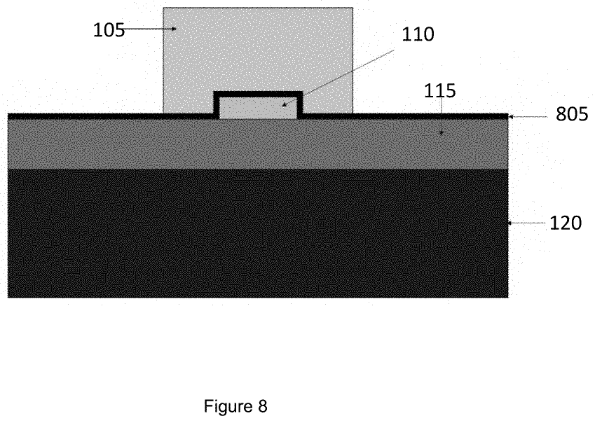

FIG. 7 shows an exemplary view of the cross-section of the exemplary LR-DLSPP waveguide arrangement with graphene below a metal stripe according to an exemplary embodiment of the present disclosure. FIG. 8 shows an exemplary view of the cross-section of the exemplary LR-DLSPP waveguide arrangement with graphene above a metal stripe according to an exemplary embodiment of the present disclosure. Incorporation of graphene or other two-dimensional (“2D”) materials in the SPP-based photodetector can improve the photodetector's performances such as responsivity and internal quantum efficiency. (See, e.g., Reference 35). One order of magnitude higher responsivity and quantum efficiency were observed for inverse-DLSPP photodetector arrangements compared to a reference structure without graphene under the same conditions. (See, e.g., Reference 13). In the exemplary LR-DLSPP design, graphene/2D materials can be incorporated either below metal strip 110 (see e.g., graphene layer 705 shown in FIG. 7) or above the metal strip 110 (see e.g., graphene layer 805 shown in FIG. 8) without disturbing the propagating mode. The LR-DLSPP waveguide with graphene can benefit from optical confinement at the Schottky metal-graphene-semiconductor interface where the Internal Photoemission (“IPE”) process can occur. This can optimize the optical intensity in graphene, and can enhance light-graphene interaction, increasing the absorption adjacent to the Schottky interface, and enhancing carriers injection from graphene to semiconductor, and in consequence, a responsivity. Most of the light in this exemplary arrangement can be absorbed in graphene, and in a 2D material, thus most of the hot carriers can be at the boundary with the semiconductor. Apart from the enhanced absorption, the relatively long relaxation time in graphene, and in a range of about 100 fs compared to about 10 fs in metals, can facilitate multiple attempts for the carrier to overcome the Schottky barrier and penetrate into the semiconductor. (See, e.g., Reference 29).

For a thin metal stripe embedded into a semiconductor, the maximum number of possible trips for hot carriers into a metal film before its energy can be reduced to Eₙ=Φ_{B} and can be given by, for example:

$$n = \frac{L}{t} ln ( \frac{hv}{{φ}_{B}} ) \qquad ( 1 )$$

where t can be metal thickness, L—the attenuation length of hot carriers, for example, the average distance over which a carrier can travel before experiencing a collisions and a reduction in energy, hv can be a photon energy and Φ_{B} can be a Schottky barrier. A carrier that may not be emitted over the Schottky barrier can be reflected toward the metal where it can eventually reach the barrier again, and thus can have another chance of emission. The total probability of photoemission can be the sum of the probabilities of carrier that have reflected off the barrier 0 to n times. Thus, for example:

P(E₀)=P₀+(1−P₀)P₁+(1−P₀)(1−P₁)P₂+ . . . +PₙΠₖ₌₀ⁿ⁻¹(1−Pₖ) (2)

where, for example:

$$P ( {E}_{k} ) = ( 1 - \sqrt{\frac{{φ}_{B}}{{E}_{k}}} ) ; ( for {E}_{k} = {E}_{0} {e}^{- k \frac{t}{L}} > {φ}_{B} \qquad ( 3 )$$

The internal quantum efficiency for a thin-film metal embedded into a semiconductor, for example, double-barrier, can be calculated using the double-barrier emission probability. Thus, for example:

$${η}_{i} = \frac{1}{hv} {\int }_{{φ}_{B}}^{hv} P ( {E}_{0} ) {dE}_{0} \qquad ( 4 )$$

The responsivity R of the photodetector can be calculated from, for example:

$$R = {γ}_{c} ( 1 - {e}^{- α l} ) \frac{q {η}_{i}}{hv} \qquad ( 5 )$$

where γ_{c} can be the coupling efficiency of the photonic mode into LR-DLSPP mode, hv can be photon energy in J, α can be the attenuation constant of the plasmonic mode, l can be the photodetector length, and q can be the electronic charge. Thus, assuming TiN as a metallic stripe supporting the LR-DLSPP with the electron mean free path of L=50 nm (e.g., L=40 nm for gold), and two different thicknesses of TiN: t=20 nm and t=40 nm as shown in the electric field maps from FIG. 5, the number of possible round trips were calculated as n=1.14 and n=2.29. Taking exemplary data for the Schottky barrier height as Φ_{B}=0.32 for a p-doped Si, the emission probability was calculated as P(E)=0.51 (e.g., for t=20 nm) and P(E)=0.37 (e.g., for t=40 nm), and the internal quantum efficiency as ηᵢ=0.64 and ηᵢ=0.46 for t=20 nm and t=40 nm thick TiN metal stripe, respectively. As shown in the electric field maps in FIG. 5, the mode power attenuation can be calculated as α=0.088 μm⁻¹ for t=20 nm and α=0.417 μm⁻¹ for t=40 nm. Assuming a photodetector length of l=20 μm and a coupling efficiency γ_{c}=92% for t=20 nm, and γ_{c}=90% for t=40 nm, the responsivity was calculated as R=0.63 A/W and R=0.52 A/W for t=20 nm and t=40 nm thick TiN stripe, respectively. None of the parameters were optimized here for maximum performance of the photodetector. For example, increases of the TiN metal stripe width from w=100 nm to w=150 nm for a metal thickness of t=20 m and for the same waveguide dimensions can cause an increase in the photodetector responsivity to R=0.73 A/W. By optimizing the plasmonic waveguide, responsivity exceeding 1.0 A/W can be possible. When compared to a 100 nm thick Au film that was deposited on top of the waveguide, the internal responsivity of R=0.026 A/W was calculated. This can be consistent with the measured data described herein where a responsivity of R=0.0125 A/W was measured.

The exemplary Schottky barrier photodetector has various advantages over prior photodetectors. For metal stripe embedded into semiconductor to achieve maximum mode power attenuation of 0.1 dB/μm, metal stripe dimensions of w=500 nm, h=20 nm or w=200 nm, h=30 nm can be beneficial. In this exemplary case, a symmetric LR-SPP mode was supported by a plasmonic waveguide. Thus, to achieve an absorption of 25 dB, the length of the photodetector of l=250 m was beneficial. For this type of the photodetector, a coupling efficiency around 90% was possible for a direct excitation of plasmonic waveguide (e.g., fiber-to-plasmonic waveguide), and a Schottky barrier was created on both sides of a metal stripe. However, this photodetector can be very hard to integrate with a standard silicon photonic platform as a mode of the plasmonic waveguide can be very big, thus preventing on-chip integration of the photodetector with a photonic platform. In contrast, the exemplary arrangement can be used where the metal stripe can be directly deposited on the semiconductor material from a top, where it was in contact with air. For this type of a structure, an asymmetric LR-SPP plasmonic mode was supported. In this exemplary case, a maximum coupling efficiency of 7% was reported (e.g., fiber-to-plasmonic waveguide) for a metal stripe dimensions of w=100 nm, h=50 nm. For these dimensions, the mode attenuation of 3 dB/μm was calculated. However, the Schottky barrier was created only on the bottom surface of the metal stripe, which can decrease the internal quantum efficiency and responsivity. The exemplary Schottky barrier photodetector can ensure at the same time: high coupling efficiency (e.g., around 90%), integration with a silicon photonic platform as a metal stripe can be implemented in the ridge/rib waveguide configuration, good mode confinement, high losses (e.g., 3 dB/μm for TiN metal stripe of w=150 nm and h=40 nm). Since a metal stripe can be embedded into a semiconductor, a Schottky barrier can be created on each side of the metal stripe, which can provide a higher efficiency of injecting the hot carriers to the semiconductor. Further, by displacing a metal stripe in the lateral direction, it can cause an increase in the Ohmic losses due to an imbalance of the mode fields on either side of the metal stripe, giving rise to the hot carriers generation.

### Exemplary Discussion

Exemplary Optical properties of TiN. To be considered as a metal for a plasmonic photodetector, TiN can illustrate good “metallic” behavior in the telecom wavelength range facilitating guiding of plasmonic modes. (See, e.g., References 41-44). To determine the optical properties of TiN, which was deposited by sputtering, variable angle spectroscopic ellipsometry measurements were performed on the 30 nm thick TiN films to obtain the optical constants.

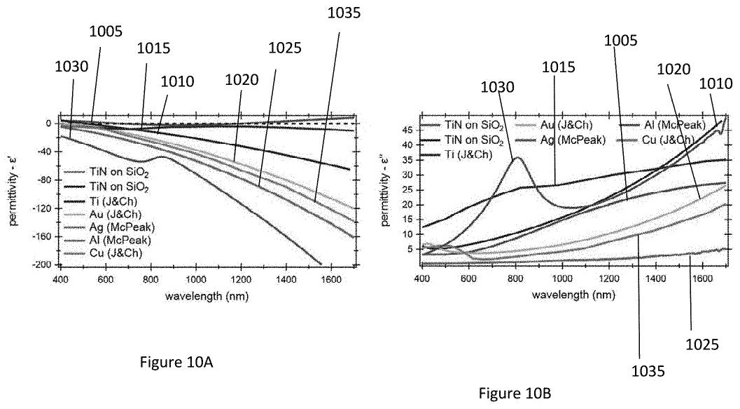

As can be seen from the exemplary graphs shown in FIGS. 10A and 10B, the magnitude of the real part of TiN can be smaller than that of other metals and the imaginary part of TiN can be larger compared to other metals. For example, the graphs shown in FIGS. 10A and 10B illustrate the magnitude of the real parts for TiN on SiO₂ (line 1005), TiN on SiO₂ under different deposition conditions (line 1010), Ti (J&Ch) (line 1015), Au (J&Ch) (line 1020), Ag (McPeak) (line 1025), Al (McPeak) (line 1030) and Cu (J&Ch) (line 1035). Thus, as shown in the graphs in FIGS. 10A and 10B TiN can provide higher absorption efficiencies over a wider wavelength range, which can enhance hot electron generation. (See, e.g., electric field maps shown in FIG. 5). It can be expected that losses exceeding 3-4 dB/μm can be achievable with TiN. A smaller real part of the permittivity usually means a higher field penetration length into the metal. However, in the exemplary design, this effect can be diminished through the LR-DLSPP arrangement where a very thin metal stripe can be used.

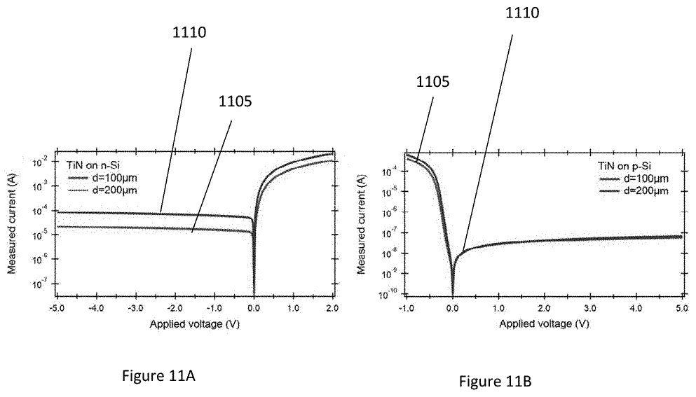

Exemplary Electrical properties of TiN—Si contacts. FIGS. 5A and 5B show the I-V dark measurements under dark current conditions for 30 nm of TiN deposited on a low refractive index material (e.g., n-Si and p-Si, respectively). The TiN can be covered by a Ti/Au contact metal in the form of disks of different diameters and annular contact regions, and then etched into devices of different sizes. The dark current of Schottky diode can be expressed by, for example:

$$I = {SA}^{*} {T}^{2} exp ( \frac{e {Φ}_{B}}{kT} ) [ exp ( \frac{e V}{kT} ) - 1 ] \qquad ( 5 )$$

where S can be the contact area, A* can be the effective Richardson constant, Φ_{B} Schottky barrier height, and V can be the applied voltage. As it can be observed from the graphs shown in FIGS. 11A and 11B, the smaller contact area can result in a smaller dark current. For example, compare d=100 μm (line 1105) with d=200 μm (line 1110). However, this behavior can be better pronounced for the TiN on n-doped Si. (See, e.g., graph shown in FIG. 11A). The dark current for the TiN on p-doped Si can be much lower compared to n-doped Si as a result of a higher Schottky barrier height (see e.g., graph shown in FIG. 11B) that can limit the carriers flow from TiN to Si.

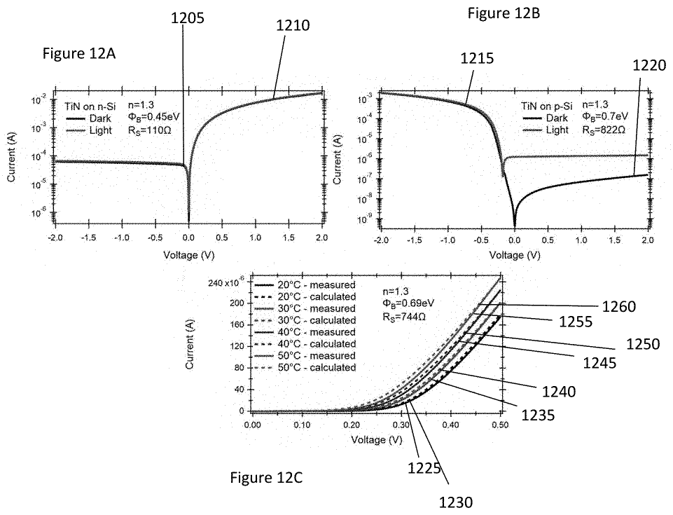

The Schottky barrier height was calculated for the TiN on n-doped Si for Φ_{B}=0.45 eV (line 1205) and Rₛ=110Ω (line 1210) (see e.g., graph shown in FIG. 12A) and p-doped Si for Φ_{B}=0.7 eV (line 1220) and Rₛ=822Ω (line 1215). (See, e.g., graph shown in FIG. 12B). For p-Si (e.g., FIG. 12B) the device shows expected rectifying behavior with the forward bias region limited by the series resistance of the contact (e.g., Rₛ=822Ω) and dark current in order of 8.1 nA for reverse bias of 0.1 V. After illumination with visible light, a photocurrent of 1.24 μA was measured for reverse bias of 0.1 V. The ideality factor for this device was calculated at n=1.3. For n-Si (e.g., FIG. 12A) the series resistance of the contact was calculated at R_{S}=110Ω and dark current of around 0.46 μA for a bias voltage of −0.1 V. After illumination, the photocurrent of 0.51 μA was measured. The ideality factor was calculated again at 1.3. For the TiN-(p-Si) contact, the device operates in photoconductive mode, where a higher optical signal affects primarily the reverse bias region, since the photogenerated process acts as an external current source added on top of the leakage (e.g., dark) current of the diode. Based on the Schottky diode thermal dependence, the reverse current across the device increases with temperature due to enhanced thermionic emission of metal electrons into the silicon. In this operation mode, the variations of reverse leakage current can be reflected to the forward bias region. For example, the graph shown in FIG. 12C shows the values for 20° C. measured (line 1225), 20° C. calculated (line 1230), 30° C. measured (line 1235), 30° C. calculated (line 1240), 40° C. measured (line 1245), 40° C. calculated (line 1250), and 50° C. measured (line 1255), 50C calculated (line 1260) Using the experimental data, the electrical parameters of the Schottky contact were extracted. The Arrhenius plot (I₀/T vs. 1/T), where I₀ can be the leakage current and T can be temperature, was used for extracting the barrier height Φ_{B′} ideality factor n, series resistance R_{S} and the effective Richardson constant A^{*38}. Thus, the potential barrier height at the TiN-(p-Si) interface, the ideality factor and the series resistance were found to be Φ_{B}=0.69 eV, n=1.3 and R_{S}=744Ω respectively, while Richardson constant was calculated at A^{*}=120.15 A/cm²K².

TABLE 1
Properties of common metals used in
the Schottky barrier photodetectors.

| | Au | Ag | Al | Cu | Ti | TiN |
|---|---|---|---|---|---|---|
| ϕ_{Bn}[eV] | 0.79- | 0.59- | 0.6- | 0.54- | 0.5 | 0.45 |
| | 0.82 | 0.62 | 0.69 | 0.57 | | |
| ϕ_{Bp}[eV] | 0.32 | 0.43- | 0.42 | 0.37- | 0.61 | 0.7 |
| | | 0.46 | | 0.4 | | |
| Work function | 5.1 | 4.2 | 4.1 | 4.6 | 4.33 | 4 |
| [eV] | | | | | | |
| Fermi energy | 5.51 | 5.48 | 11.63 | 7 | — | 4.2- |
| level [eV] | | | | | | 4.3 |
| Carrier free mean | 38 | 53 | 19 | 40 | — | 45- |
| path [nm] | | | | | | 50 |

Probability of hot electron transfer in TiN-based Schottky photodetector, TiN can provide superior performances for hot carriers generation due to enhanced absorption efficiency and increased electron mean free path. (See, e.g., References 45 and 46). It can ensure an increase in the number of hot electrons reaching the metal-semiconductor interface due to a longer effective mean free path compared to Au (see e.g., Table 1 above) and lower carrier concentration than Au that can diminish the energy loss of hot carriers due to inelastic scattering. (See, e.g., References 41 and 42). Another way to increases the hot carrier probability for transfer through the metal-semiconductor interface can be to use metals with a lower Fermi level. Thus, the cone can facilitate wave vectors of hot electrons, which can be injected into the semiconductor, which can increase as sin²θ=kₘₐₓ²/kₚ², where k_{F} can be the Fermi wave vector and kₘₐₓ can be the maximal k-vector that can facilitate transport of electrons from the metal to the semiconductor. Thus, the probability of internal photoemission of a hot electron, which can be generated by a photon with energy hω can be given by, for example:

$${P}_{0 ( h ω ) = \frac{1}{2} \frac{{E}_{F}}{ℏ ω}} \frac{{m}_{S}}{{m}_{0}} ( \frac{ℏ ω - {Φ}_{B}}{{E}_{F}} ) \qquad ( 6 )$$

where m₀, m_{S} can be the mass of the electron in the metal and the effective mass of the electron in the semiconductor respectively, and Φ_{B} can be the Schottky barrier height between metal and semiconductor. The Fermi energy can be defined as, for example:

$${E}_{F} = \frac{{ℏ}^{2} {k}_{F}^{2}}{2 {m}_{0}} = \frac{{ℏ}^{2}}{2 {m}_{0}} {( 3 {π}^{2} n )}^{2 / 3} \qquad ( 7 )$$

where n can be the carrier concentration. From the Drude fits to the dielectric function of Au and TiN (see e.g., graphs shown in FIGS. 10A and 10B), the bulk plasmon frequencies of 8.9 eV for Au and 7.2 e V for TiN were obtained. The bulk plasma frequency ωₚ can depend on the carrier concentration and the effective mass of the electron in the metal. Thus, for example:

$${ω}_{p}^{2} = \frac{{ne}^{2}}{{m}_{0} {ɛ}_{0}} \qquad ( 8 )$$

where e can be the elementary charge and ε₀ can be the permittivity of free space. Thus, the lower the plasma frequency, the lower the carrier concentration and consequently the lower the Fermi energy. As a result, the TiN has a much lower Fermi energy of 4.0-4.3 eV compared to the other common metals. (See, e.g., Table 1).

The escape cone can increase for at least 20% compared to Au, which can enhance the transmission probability from the metal to semiconductor. This can be proper for the assumption of constant density of states in the metal in the vicinity of Fermi level. However, in the exemplary photodetector, the electric field can be enhanced at all 4 metal stripe corners, that can make the density of states in valence band of silicon higher, further enhancing the probability of hot carriers to be transferred through the barrier without reflection from the metal-semiconductor interface. Introducing the surface roughness between metal and semiconductor can enhance the transmission probability (e.g., and thus injection efficiency) of hot electrons across the Schottky barrier. Up to an order of magnitude relative to the smooth interface at wavelength of 1550 nm enhancement can be achieved. (See, e.g., Reference 38).

### Exemplary Signal-to-Noise Ratio

Apart from the responsivity, another beneficial figure of merit of the photodetector can be the signal-to-noise ratio (“SNR”) (see, e.g., Reference 47) defined as, for example:

SNR=i_{signal}²/iₙₒᵢₛₑ² (9)

where i_{signal} and iₙₒᵢₛₑ can be the signal and noise currents, respectively. It can be beneficial to enhance the signal while keeping the noise at a low level. A high SNR can be achieved by reducing the dimensions of the active Schottky junction area. Furthermore, the Schottky barrier between metal and semiconductor can be as close as possible to the optimal value of approximately 0.697 e V at the telecom wavelength of 1550 nm (approximately 0.8 e V) that can be calculated from equation. (See, e.g., Reference 47). Thus, for example:

$${Φ}_{Bopt} = hv - \frac{4 kT}{e} \qquad ( 10 )$$

The Schottky barrier height between TiN and p-doped Si being calculated at Φ_{B}=0.69-0.70 eV can be based on the exemplary measurements, which can be perfect when compared with the optimal value of Φ_{Bopt}=0.697 e V for an ideal diode. (See, e.g., Reference 47). The exemplary photodetector can collect the light from a photonic waveguide, and can concentrate it into a small metal stripe with a maximum concentration located at four corners of the stripe, thus providing high responsivity and low noise.

### Exemplary Quantum Efficiency and Responsivity

For a thin metal stripe embedded into a semiconductor, the maximum number of possible trips for hot carriers into a metal film before its energy can be reduced to Eₙ=Φ_{B}, which can be given by, for example (see, e.g., References 40 and 48):

$$n = \frac{L}{t} ln \frac{hv}{{Φ}_{B}} \qquad ( 11 )$$

where t can be metal thickness, L—the attenuation length of hot carriers, for example, the average distance over which a carrier can travel before experiencing a collisions and a reduction in energy, hv can be a photon energy and Φ_{D} can be a Schottky barrier. (See, e.g., References 40 and 48). A carrier that may not be emitted over the Schottky barrier can be reflected toward the metal where it can eventually reach the barrier again and thus has another chance of emission. The total probability of photoemission can therefore be the sum of the probabilities of carriers that have reflected off the barrier 0 to n times. Thus, for example:

P(E₀)=P₀+(1−P₀)P₁+(1−P₀)(1−P₁)P₂+ . . . +PₙΠₖ₌₀ⁿ⁻¹(1−Pₖ) (12)

where

$$P ( {E}_{k} ) = ( 1 - \frac{{Φ}_{B}}{{E}_{k}} ) ; for {E}_{k} = {E}_{0 } exp ( - kt / l ) > {Φ}_{B} \qquad ( 13 )$$

The internal quantum efficiency for a thin-film metal embedded into a semiconductor, for example, double-barrier, can be calculated using the double-barrier emission probability. Thus, for example

$${η}_{i} = \frac{1}{hv} {\int }_{{Φ}_{B}}^{hv} P ( {E}_{0} ) {dE}_{θ} \qquad ( 14 )$$

The double-barrier can refer to a metal film embedded into semiconductor thus forming a Schottky contact along two metal-semiconductor interfaces (e.g., metal 910 and semiconductor 905), as shown is the diagrams in FIG. 9B. This can be compared to a single barrier as shown in the diagrams in FIG. 9A where hot electrons can only cross a barrier between metal 910 that can be in direct contact with a semiconductor 905. The responsivity R of the photodetector can be calculated from, for example:

$$R = {γ}_{c} ( 1 - exp ( α l ) ) \frac{{q}_{ni}}{hv} \qquad ( 15 )$$

where γ_{c} can be the coupling efficiency of the photonic mode into LR-DLSPP mode, hv can be photon energy, α can be the attenuation constant of the plasmonic mode, l can be the photodetector length, and q can be the electronic charge. Thus, assuming TiN as a metallic stripe supporting the LR-DLSPP with the electron mean free path of L=50 nm (L=40 nm for gold), and two different thicknesses of TiN: t=20 nm and t=40 nm as presented in FIG. 12A, the number of possible round trips were calculated as n=1.14 and n=2.29. Taking a data for the Schottky barrier height as Φ_{B}=0.45 for a n-doped Si (FIG. 12A), the emission probability was calculated as P(E)=0.31 (e.g., for t=20 nm) and P(E)=0.26 (e.g., for t=40 nm), and the internal quantum efficiency as ηᵢ=0.39 and ηᵢ=0.31 for t=20 nm and t=40 nm thick TiN metal stripe, respectively. From FIG. 5, the mode power attenuation can be calculated as α=0.088 μm⁻¹ for t=20 nm and α=0.417 μm⁻¹ for t=40 nm. Assuming a photodetector length of l=20 μm and a coupling efficiency of γ_{c}=92% for t=20 nm, and γ_{c}=90% for t=40 nm, the responsivity was calculated as R=0.37 A/W and R=0.35 A/W for t=20 nm and t=40 nm thick TiN stripe, respectively no one parameter was optimized here to maximize the performance of the photodetector. For example, an increase of the TiN metal stripe width from w=100 nm to w=150 nm for a metal thickness of t=20 nm and for the same waveguide dimensions can cause an increase in the photodetector responsivity to R=0.5 A/W. By optimizing the plasmonic waveguide and integration with graphene (see, e.g., References 43-46), a responsivity exceeding 1.0 A/W can be expected. (See, e.g., References 37 and 49). When compared with a 100 nm thick Au film deposited on top of the waveguide, the internal responsivity of R=0.013 A/W was calculated. This can be very consistent with the measured data described herein where a responsivity of R=0.0125 A/W was measured.

### Exemplary Photodetector Band Diagram

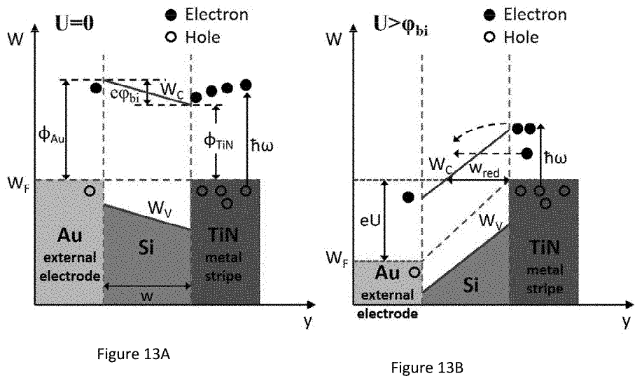

In the exemplary apparatus, the light coupled to the photodetector can excite plasmonic LR-DLSPP with the SPPs propagating on both sides of the metal stripe and dissipating its energy entirely at the metal stripe—Si interfaces. The second electrode can be placed outside of the waveguide on top of the Si rib. As the LR-DLSPP mode can be bound to the metal stripe, the second electrode can be placed very close to the waveguide/photodetector without disturbing the propagating mode. This can form a MSM photodetector. The absorbed plasmonic wave can create hot electrons in the thin metal stripe that have an increased probability of crossing the potential barrier at the metal stripe—semiconductor interface. In the asymmetric MSM arrangement where both metal electrodes can be from different metals, the built-in potential difference φ_{bi} across the silicon can be generated as a result of different Schottky barrier heights between the metals and semiconductor. (See, e.g., References 48 and 50). This can impede electron emission from the metal stripe into the silicon, and no significant current flow can be observed. (See e.g., graph shown in FIG. 13A).

When a voltage can be applied between electrodes with a positive potential at the external electrode exceeding the built-in potential difference φ_{bi}, the photoemission from the metal stripe can be enabled that have zero potential. (See e.g., graph shown in FIG. 13B). This can lead to a generation of a photocurrent from the external electrode to the metal stripe side that can depend on the optical power coupled to the waveguide/photodetector. For the operation under low dark current conditions, the asymmetric metal arrangement can facilitate the achievement of a reasonably high built-in potential difference across the silicon so that the dark current can be significantly suppressed under low operation voltages. A narrow metal stripe can suppress the dark current that can depend on the area of the Schottky barrier contact. As a result, further reduction in a dark current can be achieve by using even narrower metal stripes while the absorption into metal, for example, hot carrier generation, can be kept high by placing the metal stripe into the semiconductor ridge. This placement can disturb the propagating mode giving rise to the absorption in the metal. At the same time, the enhanced generation of hot electrons in the metal stripe entirely embedded in the semiconductor can enhance the photocurrent. As a result, the exemplary photodetector arrangement can operate under low dark current conditions while the photocurrent can be highly enhanced compared to the previously presented configurations.

### Exemplary Operation Bandwidth

The small footprint associated with strong absorption of the plasmonic mode can decrease the device capacitance such that the MSM bandwidth may not be limited by RC time constant, but rather by the transit time between electrodes. (See, e.g., Reference 51). The transit-time bandwidth fₜ of the photodetector can be proportional to the saturated drift velocity v_{c} in the semiconductor and inversely proportional to the distance between the contact electrodes d. Thus, for example:

$${f}_{t} = 0.45 \frac{{v}_{c}}{d} \qquad ( 16 )$$

Assuming a reasonable carrier saturation velocity of 6×10⁶ cm/s that can be smaller than previously known (e.g., 1.1-1.4×10⁷ cm/s) (see, e.g., References 52 and 53), and a distance between electrodes of d=400 nm, the transit-time bandwidth exceeding fₜ=67.5 GHz can be achieved. Placing a metal stripe closer to the ridge wall (see e.g., diagram shown in FIG. 1) can decrease the spacing between metal stripe and second electrode placed outside a photodetector. Thus, the transit time for carriers reaching a second electrode can be additionally decreased. Thus, the photodetector bandwidth can be increased. By reducing the spacing between both electrodes, for example, metal stripe and the electrode placed outside the waveguide to 200 nm, the bandwidth can exceed 135 GHz. Furthermore, displacing the metal electrode inside a ridge can enhance the absorption in a metal stripe resulting in more hot carriers being generated inside the metal that can contribute to the photocurrent. As a result, the internal quantum efficiency can increase.

The exemplary apparatus can include a plasmonic Schottky photodetector that can take full advantage of a metal stripe embedded into a semiconductor giving rise to the enhanced transmission probability of hot electrons from the metal to the semiconductor. Furthermore, it can provide a coupling efficiency of the photonic mode to the photodetector that can exceed 90%. As the metal stripe can be very thin, much below the electron-mean-free path for metals, most of the hot electrons can participate in transmission to the semiconductor giving rise to an external quantum efficiency and responsivity that can exceed 1.0 A/W. Furthermore, it was shown that TiN can be a perfect metallic material for the plasmonic photodetector as it can provide higher electron-mean-free path and lower Fermi energy compared to other metals. Measurements showed that a Schottky barrier height of 0.69-0.70 eV can exist between TiN and p-doped Si that can ensure maximum SNR at 1550 nm wavelength calculated theoretically at 0.697 eV. Finally, TiN can be a CMOS-compatible material that can facilitate easy integration with existing CMOS technology. As a result, the exemplary photodetector and TiN as a plasmonic material have the potential to overcome the existing responsivity and speed limitations of presently available photodetectors and become key component of future efficient and high-speed optical transmission systems.

### Exemplary Methods

Exemplary Fabrication and optical characterization of TiN on Si. Thin 30 nm-thick films of TiN were deposited on n-Si/p-Si substrates by DC reactive magnetron sputtering from a 99.99% titanium target in an Argon-Nitrogen environment. To achieve a “metallic” TiN (e.g., curves 1010 shown in FIGS. 10A and 10B), the deposition rate and substrate temperature were kept constant at 1.38 nm/min and 150° C. respectively. For TiN films deposited by atomic layer deposition resulted in oxygen incorporation in the film (e.g., curves 1005 shown in FIGS. 10A and 10B), the TiN exhibits “dielectric” properties over wavelength below 670 nm and above 1190 nm. In the wavelength range of 670-1190 nm the material shows poor “metallic” behavior with the minimum real part of permittivity εᵣ=−2.2 at wavelength of 930 nm. After deposition, the optical constants of the TiN films were derived from Spectroscopic Ellipsometry measurements performed using a J. A. Woollam M2000 variable angle spectroscopic ellipsometry system. This ellipsometry system was equipped with a rotating compensator and a high speed CCD camera. Measurements were performed at room temperature over a spectral range of 400-1700 nm and the dielectric functions were fitted to the Drude-Lorentz model. (See e.g., graphs shown in FIGS. 10A and 10B). The results were compared with other metals commonly used as metal electrodes supporting a propagating plasmonic mode. The values of permittivity for gold, silver, aluminum, copper and titanium were taken from literature. (See, e.g., References 34-37).

Exemplary FEM simulations. The exemplary modulator geometry was analyzed using two-dimensional finite element method (“FEM”) simulations at the telecom wavelength of 1550 nm using commercial software COMSOL and Lumerical. The FEM is a well-known procedure for numerical solution of partial differential equations or integral equations, where the region of interest can be subdivided into small segments and the partial differential equation can be replaced with a corresponding functional one. In the exemplary calculations, the refractive indexes of the Si waveguide and the SiO2 substrate were taken as n_{Si}=3.48 and n_{SiO2}=1.45, respectively. The Si ridge dimensions were kept constant at w=380 nm and h=200 nm, while rib thickness was kept at t=140 nm. To compare absorption losses and mode effective index two different metals were used, Au and TiN, and two different metal dimensions, for example, w=100 nm, h=20 nm, and w=150 nm, h=40 nm. The refractive index of gold (Au) and titanium nitride (TiN) was taken as n_{Au}=0.52+10.74 i and n_{TiN}=2.54+7.84 i, respectively. (See e.g., graphs shown in FIGS. 10A and 10B).

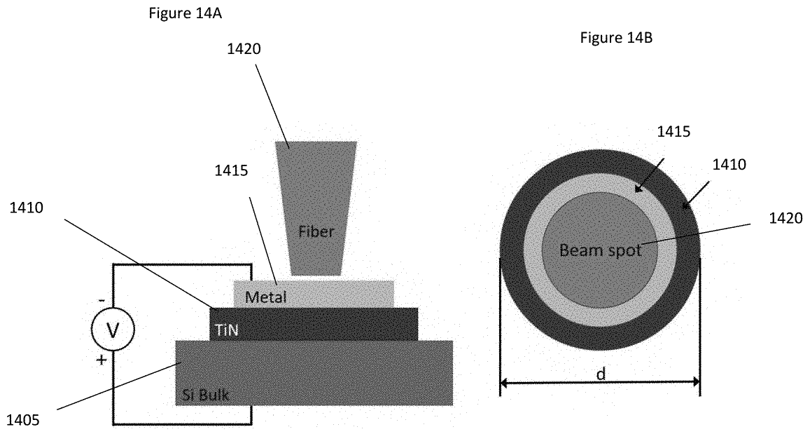

Exemplary Electrical characterization of TiN—Si contacts—I-V measurements. FIG. 14A shows an exemplary diagram of the cross-section of the exemplary measurement setup according to an exemplary embodiment of the present disclosure. FIG. 14B shows an exemplary diagram of the top down view of the measurement setup according to an exemplary embodiment of the present disclosure. To characterize the electrical properties of TiN—Si contacts, a current-voltage (I-V) characteristic of the Schottky contact was measured for both n-doped (n=2-4 Ωcm) and p-doped (n=10-20 Ωcm) silicon. The TiN 140 thickness was kept constant at h=50 nm for which a sheet resistance was measured as 50 Ω/sq. (p=2.5 10⁴ Ωcm) while its diameter changed from d=100 μm to d=200 nm. A ring shaped Au structure (e.g., metal 1415) formed the top contact on TiN/p-Si device. The substrate 1405 was used as the bottom contact. The device was probed under microscope and illuminated by a 1550 nm wavelength laser during measurements. An Er-doped fiber amplifier 1420 that can output up to 20 m W optical power was used as the infrared light source. The device was exposed to the infrared light by bringing a lens ended fiber to the close proximity of the top of the TiN layer surrounded by the ring shaped Au contact. Current-voltage measurements were performed by using a Keithley Sourcemeter. Temperature dependent current-voltage (I-V) measurements were conducted in a similar configuration. The sample was placed on a metal chuck and probed under a microscope. The temperature of the metal chuck was controlled by a thermoelectric cooler (“TEC”) and Keithley 2510 TEC Sourcemeter. I-V measurements were done at 20° C., 30° C., 40° C. and 50° C.

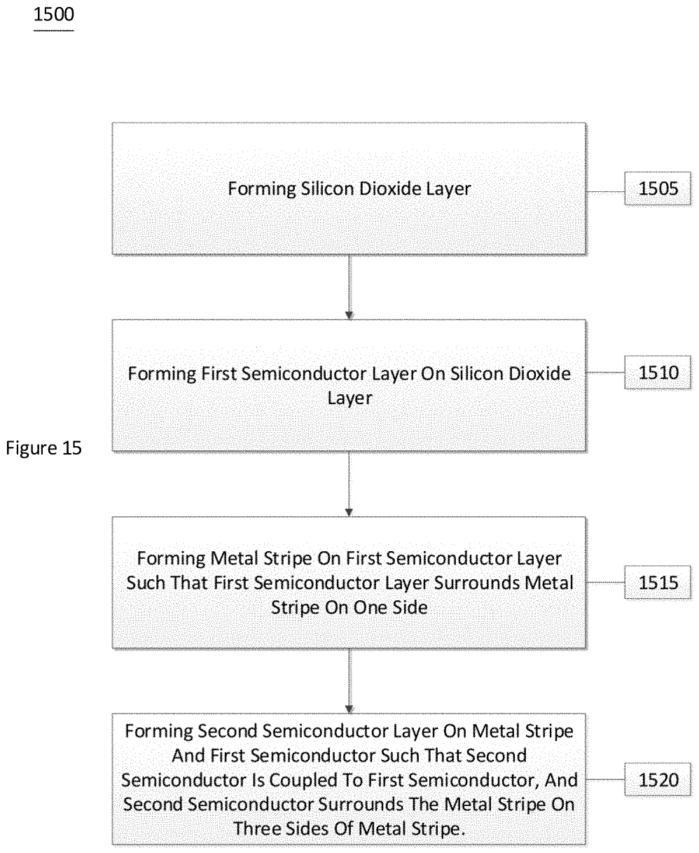

FIG. 15 shows an exemplary flow diagram of an exemplary method 1500 of fabricating a photodetector according to an exemplary embodiment of the present disclosure. For example, at procedure 1505 a silicon dioxide layer can be formed. At procedure 1510, a first semiconductor layer can be formed on the silicon dioxide layer. At procedure 1515, a metal stripe can be formed on the first semiconductor layer such that the first semiconductor layer surrounds the metal stripe on one side. At procedure 1520, a second semiconductor layer can be formed on the metal stripe and the first semiconductor such that the second semiconductor is coupled to the first semiconductor, and the second semiconductor surrounds the metal stripe on three sides of the metal stripe.

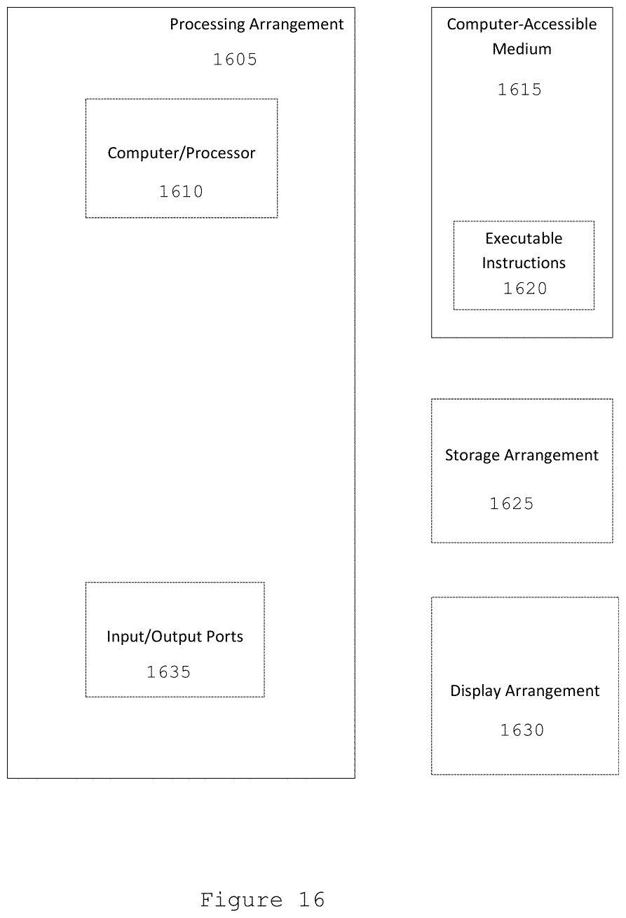

FIG. 16 shows a block diagram of an exemplary embodiment of a system according to the present disclosure. For example, exemplary procedures in accordance with the present disclosure described herein can be performed by a processing arrangement and/or a computing arrangement (e.g., computer hardware arrangement) 1605. Such processing/computing arrangement 1605 can be, for example entirely or a part of, or include, but not limited to, a computer/processor 1610 that can include, for example one or more microprocessors, and use instructions stored on a computer-accessible medium (e.g., RAM, ROM, hard drive, or other storage device).

As shown in FIG. 16, for example a computer-accessible medium 1615 (e.g., as described herein above, a storage device such as a hard disk, floppy disk, memory stick, CD-ROM, RAM, ROM, etc., or a collection thereof) can be provided (e.g., in communication with the processing arrangement 1605). The computer-accessible medium 1615 can contain executable instructions 1620 thereon. In addition or alternatively, a storage arrangement 1625 can be provided separately from the computer-accessible medium 1615, which can provide the instructions to the processing arrangement 1605 so as to configure the processing arrangement to execute certain exemplary procedures, processes, and methods, as described herein above, for example.

Further, the exemplary processing arrangement 1605 can be provided with or include an input/output ports 1635, which can include, for example a wired network, a wireless network, the internet, an intranet, a data collection probe, a sensor, etc. As shown in FIG. 16, the exemplary processing arrangement 1605 can be in communication with an exemplary display arrangement 1630, which, according to certain exemplary embodiments of the present disclosure, can be a touch-screen configured for inputting information to the processing arrangement in addition to outputting information from the processing arrangement, for example. Further, the exemplary display arrangement 1630 and/or a storage arrangement 1625 can be used to display and/or store data in a user-accessible format and/or user-readable format.

The foregoing merely illustrates the principles of the disclosure. Various modifications and alterations to the described embodiments will be apparent to those skilled in the art in view of the teachings herein. It will thus be appreciated that those skilled in the art will be able to devise numerous systems, arrangements, and procedures which, although not explicitly shown or described herein, embody the principles of the disclosure and can be thus within the spirit and scope of the disclosure. Various different exemplary embodiments can be used together with one another, as well as interchangeably therewith, as should be understood by those having ordinary skill in the art. In addition, certain terms used in the present disclosure, including the specification, drawings and claims thereof, can be used synonymously in certain instances, including, but not limited to, for example, data and information. It should be understood that, while these words, and/or other words that can be synonymous to one another, can be used synonymously herein, that there can be instances when such words can be intended to not be used synonymously. Further, to the extent that the prior art knowledge has not been explicitly incorporated by reference herein above, it is explicitly incorporated herein in its entirety. All publications referenced are incorporated herein by reference in their entireties.

### EXEMPLARY REFERENCES

The following references are hereby incorporated by reference in their entireties:
1. D. A. B. Miller, “Attojoule Optoelectronics for Low-Energy Information Processing and Communications,” J. of Lightw. Technol. 35(3), 346-396 (2017).
2. L. C. Kimerling, D-L Kwong, and K. Wada. “Scaling computation with silicon photonics,” MRS Bulletin 39, 687-695 (20140.
3. D. Thomson at el., “Roadmap on silicon photonics,” J. of Optics 18, 073003 (2016).
4. W. E. Spicer, “Photoemissive, Photoconductivite, and Optical Absorption Studies of Alkali-Antimony Compounds,” Phys. Rev. 112, 114-122 (1958).
5. W. E. Spicer, “Negative affinity 3-5 photocathodes: Their physics and technology,” Appl. Phys. 12, 115-130 (1977).
6. D. K. Gramotnev, and S. I. Bozhevolnyi, “Plasmonic beyond the diffraction limit,” Nat. Photonics 4, 83-91 (2010).
7. W. L. Barnes, A. Dereux, and T. W. Ebbesen, “Surface plasmon subwavelength optics,” Nature 424, 824-830 (2003).
8. T. Holmgaard, J. Gosciniak, and S. I. Bozhevolnyi, “Long-range dielectric-loaded surface plasmon-polariton waveguides,” Opt. Express 18(22), 23009-23015 (2010).
9. J. Gosciniak, T. Holmgaard, and S. 1. Bozhevolnyi, “Theoretical Analysis of Long-Range Dielectric-Loaded Surface Plasmon Polariton Waveguides,” J. of Lightw. Technol. 29(10), 1473-1481 (2011).
10. X. Shi, X. Zhang, Z. Han, U. Levy, and S. I. Bozhevolnyi, “CMOS-Compatible Long-Range Dielectric-Loaded Plasmonic Waveguides,” J. of Lightw. Technol. 31(21), 3361-3367 (2013).
11. B. Sturlesi, M. Grajower, N. Mazurski, and U. Levy, “Integrated amorphous silicon-aluminium long-range surface plasmon polariton (LR-SPP) waveguides,” APL Photonics 3, 036103 (2018).
12. S. Muchlbrandt, A. Melikyan, T. Harter, K. Kohnle, A. Muslija, P. Vincze, S. Wolf, P. Jakobs, Y. Fedoryshyn, W. Freude, J. Leuthold, C. Koos, and M. Kohl, “Silicon-plasmonic internal-photoemission detector for 40 Gbit % s data reception,” Optica 3(7), 741-747 (2016).
13. I. Goykhman, U. Sassi, B. Desiatov, N. Mazurski, S. Milana, D. de Fazio, A. Eiden, J. Khurgin, U. Levy, and A. C. Ferrai, “On-Chip Integrated, Silicon-Graphene Plasmonic Schottky Photodetector for High Responsivity and Avalanche Photogain,” Nano Lett. 16(5), 3005-3013 (2016).
14. I. Goykhman, B. Desiatov, J. Khurgin, J. Shappir, and U. Levy, “Locally Oxidized Silicon Surface-Plasmon Schottky Detector for Telecom Regime,” Nano Lett. 11(6), 2219-2224 (2011).
15. I. Goykhman, B. Desiatov, J. Khurgin, J. Shappir, and U. Levy, “Waveguide based compact silicon Schottky photodetector with enhanced responsitity in the telecom spectral band,” Opt. Express 20(27), 28594 (2012).
16. I. Goykhman, B. Desiatov, J. Shappir, J. B. Khurgin, and U. Levy, “Model for quantum efficiency of guided mode plasmonic enhanced silicon Schottky detectors,” arXiv:1401.2624 (2014).
17. N. Othman, and P. Berini, “Nanoscale Schottky contact surface plasmon “point detectors” for optical beam scanning applications,” Appl. Optics 56(12), 3329-3334 2017).
18. M. W. Knight, Y. Wang, A. S. Urban, A. Sobhani, B. Y. Zheng, P. Nordlander, and N. J. Halas, “Embedding Plasmonic Nanostructure Diodes Enhances Hot Electron Emission,” Nano Lett. 13, 1687-1692 (2013).
19. A. Giugni, B. Torre, A. Toma, M. Francardi, M. Malerba, A. Alabastri, R. P. Zaccaria, M. I. Stockman, and E. Di Fabrizio, “Hot-electron nanoscopy using adiabatic compression of surface plasmons,” Nat. Nanotech. 8, 845-852 (2013).
20. R. Sundararaman, P. Narang, A S. Jermyn, W. A. Goddard III, and H. A. Atwater, “Theoretical predictions for hot-carrier generation from surface plasmon decay,” Nat. Commun. 5:5788 doi: 10.1038/ncomms6788 (2014).
21. P. Narang, R. Sundararaman, and H. A. Atwater, “Plasmonic hot carrier dynamics in solid-state and chemical systems for energy conversion,” Nanophotonics 5(1), 96-1 I (2016).
22. A. J. Leenheer, P. Narang, N. S. Lewis, and H. A. Atwater, “Solar energy conversion via hot electron internal photoemission in metallic nanostructures: Efficiency estimates,” J. of Appl. Phys. 115, 134301 (2014).
23. C. Clavero, “Plasmon-induced hot-electron generation at nanoparticle/metal-oxide interfaces for photovoltaic and photocatalytic devices,” Nat. Photonics 8, 95-103 (2014).
24. M. L. Brongersma, N. J. Halas, and P. Nordlander, “Plasmon-induced hot carrier science and technology,” Nat. Nanotechnology 10, 25-34 (2015).
25. W. Li and J. G. Valentine, “Harvesting the loss: surface plasmon-based hot electron photodetection,” Nanophotonics 6(1), 177-191 (2017).
26. P. J. Schuck. “Hot electrons go through the barrier,” Nat. Nanotechnology 8, 799-800 (2013).
27. A. Naldoni, U. Guler, Z. Wang, M. Marelli, F. Malara, X. Meng, L. V. Besteiro, A. O. Govorov, A. V. Kildishev, A. Boltasseva, and V. M. Shalaev, “Broadband Hot-Electron Collection for Solar Water Splitting with Plasmonic Titanium Nitride,” Adv. Optical Mater. 5, 1601031 (2017).
28. S. Ishii, S. L. Shinde, W. Jevasuwan, N. Fukata, and T. Nagao, “Hot Electron Excitation from Titanium Nitride Using Visible Light,” ACS Photonics 3, 1552-1557 (2016).
29. U. Levy, M. Grajower, P. A. D. Goncalves, N. A. Mortensen, and J. B. Khurgin, “Plasmonic silicon Schottky photodetectors: The physics behind graphene enhanced internal photoemission,” APL Photonics 2, 026103 (2017).
30. Ch. Scales, 1. Breukelaar, and P. Berini, “Surface-plasmon Schottky contact detector based on a symmetric metal stripe in silicon,” Opt. Letters 35(4), 529-531 (2010).
31. Ch. Scales, and P. Berini, “Thin-Film Schottky Barrier Photodetector Models,” IEEE J. of Quantum Electronics 46(5), 633-643 (2010).
32. A. Akbari, and P. Berini, “Schottky contact surface-plasmon detector integrated with an asymmetric metal stripe waveguide,” Appl. Phys. Lett. 95, 021104 (2009).
33. J. Fukijata, T. Ishi, D. Okamoto, K. Nishi, and Ohashi, “Highly Efficient Surface-Plasmon Antenna and its Application to Si Nano-Photodiode,” in LEOS 2006-19th Annual Meeting of the IEEELasers and Electro-Optics Society, 476-477 (2006).
34. S. Muhlbrandt, J. Leuthold, and M. Kohl, “Plasmonic component and plasmonic photodetector and method for producing SAME,” Pub. No.: US 2017/0194514 A1, Jul. 6 2017.
35. A. Colli, S. A. Awan, A. Lombardo, T. J. Echtermeyer, T. S. Kulmala, and A. C. Ferrari, “Graphene-based MIM diode and associated methods,” Patent No.: U.S. Pat. No. 9,202,945 B2, Dec. 1 2015.
36. Ch. A. Scales, and P. S. J. Berini, “Schottky Barrier Photodetectors,” Patent No.: U.S. Pat. No. 7,026,701 B2, Apr. 11 2006.
37. Goykhman, 1. et al. On-chip integrated, silicon-graphene plasmonic schottky photodetector with high responsivity and avalanche photogain. Nano Lett. 16, 3005-3013 (2016).
38. Grajower, M., Levy, U. & Khurgin, J. B. The role of surface roughness in plasmonic-assisted internal photoemission schottky photodetectors. Acs Photonics 5, 4030-4036 (2018).
39. Goykhman, I., Desiatov, B., Khurgin, J., Shappir, J. & Levy, U. Waveguide based compact silicon schottky photodetector with enhanced responsivity in the telecom spectral band. Opt. Express 20, 28594-28602 (2012).
40. Scales, C. & Berini, P. Thin-film schottky barrier photodetector models. IEEE J. Quantum Electron. 46, 633-643 (2010).
41. West, P. R. et al. Searching for better plasmonic materials. Laser & Photonics Rev. 4, 795-808 (2010).
42. Naik, G. V., Shalaev, V. M. & Boltasseva, A. Alternative plasmonic materials: beyond gold and silver. Adv. Mater. 25, 3264-3294 (2013).
43. Gosciniak, J., Justice, J., Khan, U., Modreanu, M. & Corbett, B. Study of high order plasmonic modes on ceramic nanodisks. Opt. Express 25, 5244-5254 (2017).
44. Gosciniak, J., Justice, J., Khan, U. & Corbett, B. Study of tin nanodisks with regard to application for heat-assisted magnetic recording. MRS Adv. 1, 317-326 (2016).
45. Naldoni, A. et al. Broadband hot-electron collection for solar water splitting with plasmonic titanium nitride. Adv. Opt. Mater. 5, 1601031 (2017).
46. Ishii, S., Shinde, S. L., Jevasuwan, W., Fukata, N. & Nagao, T. Hot electron excitation from titanium nitride using visible light. ACS Photonics 3, 1552-1557 (2016).
47. Grajower, M. et al. Optimization and experimental demonstration of plasmonic enhanced internal photoemission silicon schottky detectors in the mid-ir. ACS Photonics 4, 1015-1020 (2017).
48. Scales, C., Breukelaar, 1. & Berini, P. Surface-plasmon schottky contact detector based on a symmetric metal stripe in silicon. Opt. Lett. 35, 529-531 (2010).
49. Levy, U., Grajower, M., Goncalves, P., Mortensen, N. A. & Khurgin, J. B. Plasmonic silicon schottky photodetectors: The physics behind graphene enhanced internal photoemission. Apl Photonics 2, 026103 (2017).
50. Akbari, A. & Berini, P. Schottky contact surface-plasmon detector integrated with an asymmetric metal stripe waveguide. Appl. Phys. Lett. 95, 021104 (2009).
51. Wahl, P. et al. Energy-per-bit limits in plasmonic integrated photodetectors. IEEE J. Sel. Top. Quantum Electron. 19, 3800210-3800210 (2013).
52. Ding, Y. et al. Ultra-compact graphene plasmonic photodetector with the bandwidth over 110 ghz. arXiv preprint arXiv:1 808.04815 (2018).
53. Bonmann, M., Vorobiev, A., Andersson, M. A. & Stake, J. Charge carrier velocity in graphene field-effect transistors. Appl. Phys. Lett. 111, 233505 (2017).

What is claimed is:

1. A photodetector, comprising:
a metal contact;
a metal stripe coupled to the metal contact; and
at least one semiconductor surrounding the metal stripe on at least three sides of the metal stripe.

2. The photodetector of claim 1, wherein the at least one semiconductor surrounds the metal stripe on at least four sides.

3. The photodetector of claim 1, wherein the at least one semiconductor surrounds the metal stripe on at least five sides.

4. The photodetector of claim 1, further comprising a silicon dioxide layer coupled to the at least one semiconductor.

5. The photodetector of claim 1, further comprising a graphene layer located between the metal stripe and the at least one semiconductor.

6. The photodetector of claim 1, wherein the at least one semiconductor includes a first semiconductor and a second semiconductor.

7. The photodetector of claim 6, wherein the first semiconductor surrounds the metal stripe on three sides, and wherein the second semiconductor surrounds the metal stripe on one side.

8. The photodetector of claim 6, further comprising a low refractive index layer and a graphene layer, wherein:
the first semiconductor is disposed on the low refractive index layer, and
the graphene layer is disposed on the first semiconductor layer.

9. The photodetector of claim 8, wherein the metal stripe is disposed on the graphene layer such that the graphene layer surrounds the metal stripe on one side.

10. The photodetector of claim 9, wherein the second semiconductor surrounds the metal stripe on at least four sides, and wherein the second semiconductor is coupled to the graphene layer.

11. The photodetector of claim 6, further comprising a low refractive index layer, wherein the semiconductor layer is disposed on the low refractive index layer, and wherein the semiconductor layer surrounds the metal stripe on one side.

12. The photodetector of claim 11, further comprising a graphene layer surrounding the metal stripe on at least four sides, and wherein the second semiconductor is coupled to the graphene layer.

13. The photodetector of claim 1, wherein the metal contact is disposed on the at least one semiconductor.

14. The photodetector of claim 1, further comprising a further metal contact disposed on the at least one semiconductor.

15. The photodetector of claim 1, wherein the metal contact and the metal stripe are composed of titanium nitride.

16. The photodetector of claim 1, wherein the at least one semiconductor is an insulator.

17. The photodetector of claim 1, wherein the photodetector is configured to operate at a wavelength of between about 1260 nm to about 1625 nm.

18. The photodetector of claim 1, wherein the metal stripe is a plasmonic stripe.

19. A photodetector, comprising:
a first semiconductor;
a first metal contact disposed on the first semiconductor,
a metal stripe coupled to the first metal contact, wherein the first semiconductor surrounds the metal stripe on one side of the metal stripe;
a second semiconductor surrounding the metal stripe on at least three sides of the metal stripe; and
a second metal contact disposed on the first semiconductor.

20. A method of fabricating a photodetector, comprising:
forming a low refractive index layer;
forming a first semiconductor layer on the low refractive index layer;
forming a metal stripe on the first semiconductor layer such that the first semiconductor layer surrounds the metal stripe on one side; and
forming a second semiconductor layer on the metal stripe and the first semiconductor such that the second semiconductor is coupled to the first semiconductor, and such that the second semiconductor surrounds the metal stripe on three sides of the metal stripe.
